(19) United States
(12) Patent Application Publication
(10) Pub. No.: US 2019/0074051 A1
(43) Pub. Date: Mar. 7, 2019

(54) MEMORY SYSTEM AND REFRESH CONTROL METHOD THEREOF

(71) Applicant: MEDIATEK INC., Hsin-Chu (TW)

(72) Inventors: Chia-Fu CHANG, Taipei City (TW); Hsiang-I HUANG, Hsinchu City (TW); Bo-Wei HSIEH, Hsinchu City (TW); Szu-Ying CHENG, Zhubei City (TW); Yu-Hsien TSAI, Hsinchu City (TW)

(21) Appl. No.: 15/995,187

(22) Filed: Jun. 1, 2018

Related U.S. Application Data
(60) Provisional application No. 62/555,097, filed on Sep. 7, 2017.

(51) Int. Cl. G11C 11/406

(52) U.S. Cl. CPC G11C 11/40615; G11C 11/40622

(57) ABSTRACT

A refresh control method for a memory system is provided. The memory system includes a dynamic random access memory with a register set and a memory cell array. The refresh control method includes the following steps. Firstly, a masking command or an unmasking command is issued, and thus the register set is updated. A first region of the memory cell array is set as a masked region according to the masking command. A second region of the memory cell array is set as an unmasked region according to the unmasking command. Then, a refresh command is issued to the dynamic random access memory. According to the refresh command, a refresh action is performed on the second region of the memory cell array.

This application claims the benefit of U.S. provisional application Ser. No. 62/555,097, filed Sep. 7, 2017, the disclosure of which is incorporated by reference herein in its entirety.

### FIELD OF THE INVENTION

The invention relates to a memory and a controller, and more particularly to a memory system and a refresh control method.

### BACKGROUND OF THE INVENTION

FIG. 1 schematically illustrates the architecture of a conventional memory system. As shown in FIG. 1, the memory system 100 comprises a memory controller 120 and a dynamic random access memory (DRAM) 110.

Generally, the memory controller 120 is connected with a host (not shown). Moreover, the memory controller 120 may write data from the host to the DRAM 110, or the memory controller 120 may read data from the DRAM 110 and transmit the data to the host. For example, a double data rate DRAM (also abbreviated as DDR DRAM) is one of the common DRAMs. Moreover, a third generation DDR DRAM is abbreviated as DDR3 DRAM, and a fourth generation DDR DRAM is abbreviated as DDR4 DRAM.

The DRAM 110 comprises a memory cell array with plural memory cells. Each memory cell may comprise a storage capacitor. The DRAM 110 further comprises a refreshing circuit. The refreshing circuit is used for refreshing the memory cells of the memory cell array in order to prevent data loss of the storage capacitors.

For preventing data loss of the storage capacitors, the refreshing circuit refreshes all memory cells of the memory cell array according to a refresh information. For example, the refresh information may include a refresh rate parameter indicating a refresh duration, which is equal to the refresh rate parameter multiplied by a refresh window t_{REFW}. When the refresh duration is determined, the refresh rate is also determined. Since the data loss rate of the DRAM 110 is related to the ambient temperature, the DRAM 110 can automatically change the refresh information according to the ambient temperature. Moreover, the updated refresh information is stored in a register of the DRAM 110.

When the memory controller 120 is disabled or in a sleep state, the refreshing circuit of the DRAM 110 automatically performs a self-refresh action to prevent data loss of the memory cell array according to the refresh information in the register of the DRAM 110.

When the memory controller 120 is in a normal working state, the memory controller 120 has to read the refresh information from the register of the DRAM 110 at first. Then, the memory controller 120 periodically issues a refresh command to the DRAM 110 according to the read refresh information. According to the refresh command, the refreshing circuit of the DRAM 110 performs a refresh action to prevent data loss of the memory cell array,

For example, the memory cell array of the DRAM 110 includes a plurality of banks, and an all bank refresh cycle time tREFC_{ab} is defined in the DRAM specification. When the memory controller 120 is in the normal working state, the memory controller 120 has to comply with the all bank refresh cycle time tREFC_{ab} to periodically issue all-bank refresh commands or periodically issue per-bank refresh commands. The all bank refresh cycle time tREFC_{ab} is a time interval between two consecutive all-bank refresh commands. Furthermore, the all bank refresh cycle time tREFCab divided by the total number of banks is a per-bank refresh cycle time indicating a time interval between two consecutive per-bank refresh commands,

As mentioned above, the refreshing circuit refreshes all memory cells of the memory cell array when the memory controller 120 is in the sleep state or the normal working state,

However, the conventional technology still has some drawbacks. For example, a portion of the memory cell array of the DRAM 110 stores invalid data or stores no data. Since the refresh action is performed on the entire of the memory cell array, the resources of the memory controller 120 are wasted. Similarly, the way of performing the self-refresh action on the entire of the memory cell array also wastes the resources of the DRAM 110.

### SUMMARY OF THE INVENTION

An embodiment of the invention provides a refresh control method for a memory system. The memory system comprises a dynamic random access memory with a register set and a memory cell array. The refresh control method comprises steps of: updating the register set to divide the memory cell array into a first region and a second region, wherein the first region is set as a masked region, and a second region is set as an unmasked region; and issuing a refresh command to the dynamic random access memory, wherein according to the refresh command, a refresh action is performed on the second region of the memory cell array.

Another embodiment of the invention provides a memory controller. The memory controller is connected with a dynamic random access memory. The dynamic random access memory comprising a memory cell array, a register set and a refreshing circuit. Furthermore, the memory controller is capable of setting the register set. The memory controller sets a first region of the memory cell array as a masked region and sets a second region of the memory cell array as an unmasked region. After the memory controller issues a refresh command to the dynamic random access memory, the refreshing circuit performs a refresh action on the second region of the memory cell array according to the refresh command.

Numerous objects, features and advantages of the invention will be readily apparent upon a reading of the following detailed description of embodiments of the invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the invention will become more readily apparent to those ordinarily skilled in the art after reviewing the following detailed description and accompanying drawings, in which:

FIG. 1 (prior art) schematically illustrates the architecture of a conventional memory system;

FIG. 2 schematically illustrates the architecture of a memory system according to a first embodiment of the invention;

FIG. 3A schematically illustrates the relationship between the memory cell array and the masking status register of the DRAM in a bank mask mode;

FIG. 3B schematically illustrates the relationship between the memory cell array and the masking status register of the DRAM in a segment mask mode;

FIG. 3C schematically illustrates the relationship between the memory cell array and the masking status register of the DRAM in a hybrid mode;

FIG. 4 schematically illustrates the architecture of a memory system according to a second embodiment of the invention;

FIG. 5 schematically illustrates the architecture of a memory system according to a third embodiment of the invention; and

FIG. 6 is a schematic timing diagram illustrating the relationship between the masked command and the refresh rate according to the third embodiment of the invention.

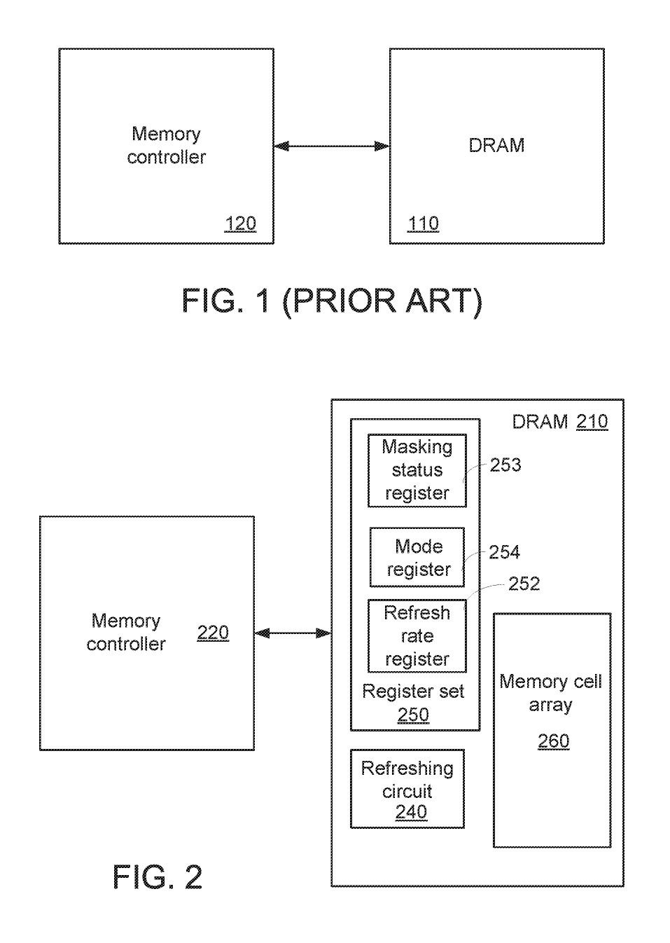

### DETAILED DESCRIPTION OF PREFERRED EMBODIMENTS

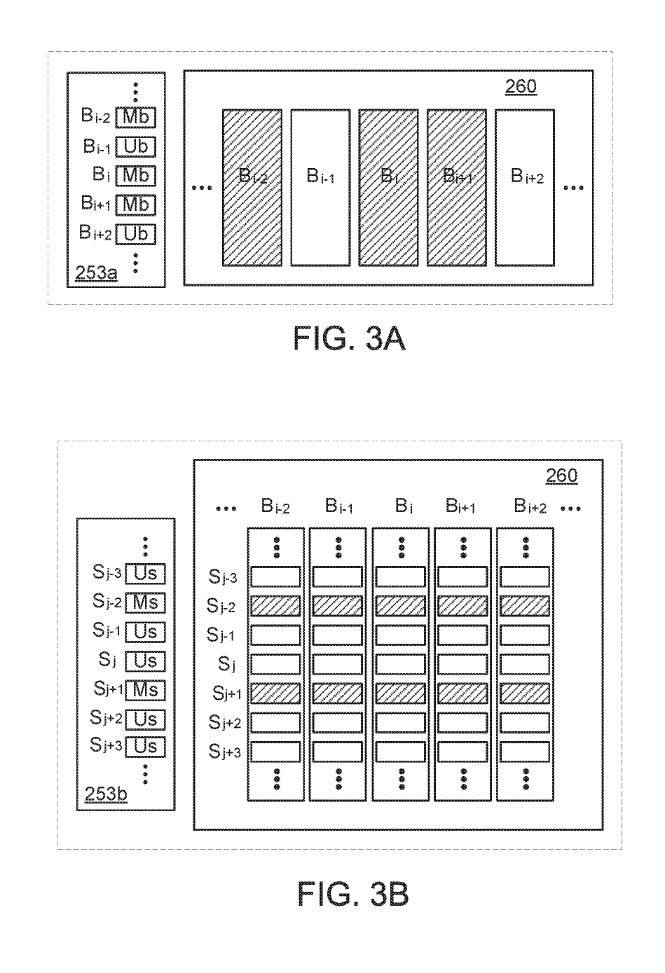

FIG. 2 schematically illustrates the architecture of a memory system according to a first embodiment of the invention. The memory system is applied to a self-refresh operation of the DRAM.

As shown in FIG. 2, the memory system comprises a memory controller 220 and a dynamic random access memory (DRAM) 210. The memory controller 220 is connected with a host (not shown). Moreover, the memory controller 220 may write data from the host to the DRAM 210, or the memory controller 220 may read data from the DRAM 210 and transmit the data to the host.

In this embodiment, the DRAM 210 comprises a memory cell array 260, a register set 250 and a refreshing circuit 240. The register set 250 comprises a masking status register 253, a refresh rate register 252 and a mode register 254. In another embodiment, the refresh rate register 252 and the masking status register 253 may be included in the mode register 254.

Since the data loss rate of the DRAM 210 is related to the ambient temperature, the DRAM 210 can automatically change the refresh information according to the ambient temperature. Moreover, the updated refresh information is stored in the refresh rate register 252 of the DRAM 210. For example, as the ambient temperature increases, the refresh rate parameter included in the refresh information becomes smaller and the refresh duration becomes shorter indicating a faster refresh rate. Whereas, as the ambient temperature decreases, the refresh rate parameter included in the refresh information becomes larger and the refresh duration becomes longer indicating a slower refresh rate.

Moreover, the refresh information stored in the refresh rate register 252 is capable of being updated by the DRAM 210. The memory controller 220 cannot modify the contents of the refresh rate register 252 and the memory controller 220 only can read the refresh information from the refresh rate register 252.

In this embodiment, the memory cell array 260 is divided into plural regions. The masking status register 253 is mapped to all regions of the memory cell array 260. Moreover, the memory controller 220 selectively issues a masking command or an unmasking command to the masking status register 253. According to the masking command or the unmasking command, the masking status register 253 is updated. Consequently, the regions of the memory cell array 260 are selectively set as masked regions or unmasked regions. Moreover, the unmasked regions store valid data, and the masked regions store invalid data.

When the memory controller 220 is disabled or in a sleep state, the refreshing circuit 240 of the DRAM 210 performs a self-refresh action. When the self-refresh action is performed, a DRAM performs refresh on the unmasked regions according to the contents of the masking status register 253. The refreshing circuit 240 then can perform the self-refresh action on the unmasked regions.

The memory cell array 260 comprises plural memory banks. Each memory bank comprises plural memory segments. In other words, the plural regions are plural memory banks or plural memory segments.

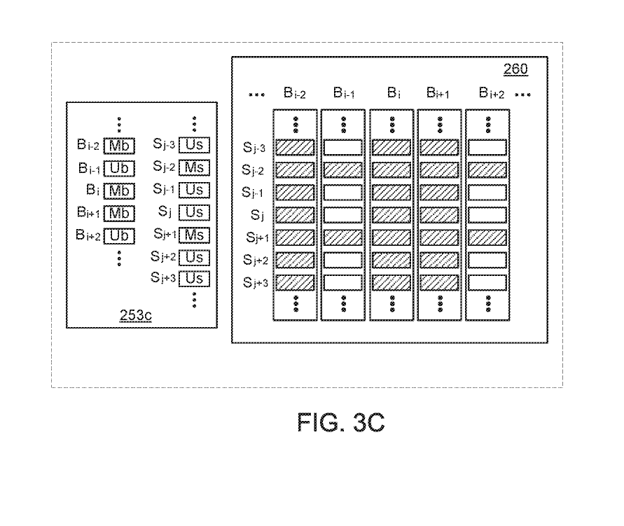

FIG. 3A schematically illustrates the relationship between the memory cell array and the masking status register of the DRAM in a bank mask mode. As shown in FIG. 3A, the memory cell array 260 comprises plural memory banks Bᵢ₋₂˜Bᵢ₊₂. The masking status register 253a is mapped to the memory banks Bᵢ₋₂˜Bᵢ₊₂ of the memory cell array 260.

In the bank mask mode, the memory controller 220 issues the masking command or the unmasking command to set the masking status register 253a. Consequently, the memory banks of the memory cell array 260 are selectively set as masked memory banks (Mb) or unmasked memory banks (Ub). For example, the masked memory banks (Mb) comprise the memory banks Bᵢ₋₂, Bᵢ and Bᵢ₊₁, and the unmasked memory banks (Ub) comprise the memory banks Bᵢ₋₁ and Bᵢ₊₂. According to the masking command, the unmasked memory bank is set as the masked memory bank. According to the unmasking command, the masked memory bank is set as the unmasked memory bank.

When the memory controller 220 is disabled or in a sleep state, the refreshing circuit 240 of the DRAM 210 performs the self-refresh action on the unmasked memory banks according to the contents of the masking status register 253a. That is, the refreshing circuit 240 performs the self-refresh action on the unmasked memory banks Bᵢ₋₁ and Bᵢ₊₂ in response to a DRAM refresh pointer. Also, the DRAM refresh pointer can automatically jump over the masked memory banks Bᵢ₋₂, Bᵢ and Bᵢ₊₁.

The above method can prevent data loss of the unmasked memory banks Bᵢ₋₁ and Bᵢ₊₂ of the memory cell array 260. On the other hand, the masked memory banks Bᵢ₋₂, Bᵢ and Bᵢ₊₁ store the invalid data. Even if the data of the masked memory bank are lost, the memory system is not adversely affected.

FIG. 3B schematically illustrates the relationship between the memory cell array and the masking status register of the DRAM in a segment mask mode, As shown in FIG. 3B, the memory cell array 260 comprises plural memory banks Bᵢ₋₂˜Bᵢ₊₂. Each of the memory banks comprises plural memory segments Sⱼ₋₃˜Sⱼ₊₃. The masking status register 253b is mapped to the memory segments Sⱼ₋₃˜Sⱼ₊₃ of the memory cell array 260.

In the segment mask mode, the memory controller 220 issues the masking command or the unmasking command to set the masking status register 253b. Consequently, the memory segments of the memory cell array 260 are selectively set as masked memory segments (Ms) or unmasked memory segments (Us). For example, the masked memory segments (Ms) comprise the memory segments Sⱼ₋₂ and Sⱼ₊₁, and the unmasked memory segments (Us) comprise the memory segments Bⱼ₋₃, Sⱼ₋₁, Sⱼ, Sⱼ₊₂ and Sⱼ₊₃. According to the masking command, the unmasked memory segment is set as the masked memory segment. According to the unmasking command, the masked memory segment is set as the unmasked memory segment.

When the memory controller 220 is disabled or in a sleep state, the refreshing circuit 240 of the DRAM 210 performs the self-refresh action on the unmasked memory segments according to the contents of the masking status register 253b. That is, the refreshing circuit 240 performs the self-refresh action on the unmasked memory segments Sⱼ₋₃, Sⱼ₋₁, Sⱼ, Sⱼ₊₂ and Sⱼ₊₃ in response to the DRAM refresh pointer. Also, the DRAM refresh pointer can automatically jump over the masked memory segments Sⱼ₋₂ and Sⱼ₊₁.

The above method can prevent data loss of the unmasked memory segments Sⱼ₋₃, Sⱼ₋₁, Sⱼ, Sⱼ₊₂ and Sⱼ₊₃ of the memory cell array 260. On the other hand, the masked memory segments Sⱼ₋₂ and Sⱼ₊₁ store the invalid data, Even if the data of the masked memory segments are lost, the memory system is not adversely affected.

FIG. 3C schematically illustrates the relationship between the memory cell array and the masking status register of the DRAM in a hybrid mode. The hybrid mode is a mixed mode of the bank mask mode and the segment mask mode. As shown in FIG. 3C, the memory cell array 260 comprises plural memory banks Bᵢ₋₂˜Bᵢ₊₂. Each of the memory banks comprises plural memory segments Sⱼ₋₃˜Sⱼ₊₃. The masking status register 253c is mapped to the memory banks Bᵢ₋₂˜Bᵢ₊₂ and the memory segments Sⱼ₋₃˜Sⱼ₊₃ of the memory cell array 260.

In the hybrid mode, the memory controller 220 issues the masking command or the unmasking command to set the masking status register 253c. Consequently, the memory banks of the memory cell array 260 are selectively set as masked memory banks (Mb) or unmasked memory banks (Ub), and the memory segments of the memory cell array 260 are selectively set as masked memory segments (Ms) or unmasked memory segments (Us). For example, the masked memory banks (Mb) comprise the memory banks Bᵢ₋₂, Bᵢ and Bᵢ₊₁, and the unmasked memory banks (Ub) comprise the memory banks Bᵢ₋₁ and Bᵢ₊₂. In addition, the masked memory segments (Ms) comprise the memory segments Sⱼ₋₃ and Sⱼ₊₁, and the unmasked memory segments (Us) comprise the memory segments Sⱼ₋₃, Sⱼ₋₁, Sⱼ, Sⱼ₊₂ and Sⱼ₊₃. According to the masking command, the unmasked memory bank is set as the masked memory bank or the unmasked memory segment is set as the masked memory segment. According to the unmasking command, the masked memory bank is set as the unmasked memory bank, or the masked memory segment is set as the unmasked memory segment.

When the memory controller 220 is disabled or in a sleep state, the refreshing circuit 240 of the DRAM 210 performs the self-refresh action on the unmasked memory banks and the unmasked segments according to the contents of the masking status register 253c. That is, the refreshing circuit 240 performs the self-refresh action on the memory segments Sⱼ₋₃, Sⱼ₋₁, Sⱼ, Sⱼ₊₂ and Sⱼ₊₃ of the unmasked memory banks Bᵢ₋₁ and Bᵢ₊₂ in response to the DRAM refresh pointer.

The above method can prevent data loss of the unmasked memory segments Sⱼ₋₃, Sⱼ₋₁, Sⱼ, Sⱼ₊₂ and Sⱼ₊₃ of the unmasked memory banks Bᵢ₋₁ and Bᵢ₊₂. On the other hand, the masked memory segments Sⱼ₋₂ and Sⱼ₊₁ and the memory segments Sⱼ₋₂ and Sⱼ₊₁ store the invalid data. Even if the data of the masked memory segments are lost, the memory system is not adversely affected.

From the above descriptions, the memory controller 220 can set the masking status register 253 of the register set 250. Consequently, the plural regions of the memory cell array 260 are selectively set as the masked regions or the unmasked regions. When the memory controller 220 is disabled or in a sleep state, the refreshing circuit 240 of the DRAM 210 performs the self-refresh action on the unmasked regions according to the contents of the masking status register 253.

When the memory controller 220 is in a normal working state, the memory controller 220 can set the masking status register 253 of the register set 250. In addition, the memory controller 220 periodically issues a refresh command to the DRAM 210. According to the refresh command, the refreshing circuit of the DRAM 210 performs a refresh action to prevent data loss of the memory cell array 260. Similarly, the memory controller 220 issues the masking command and the unmasking command to set the masking status register 253, and the detailed descriptions thereof are omitted.

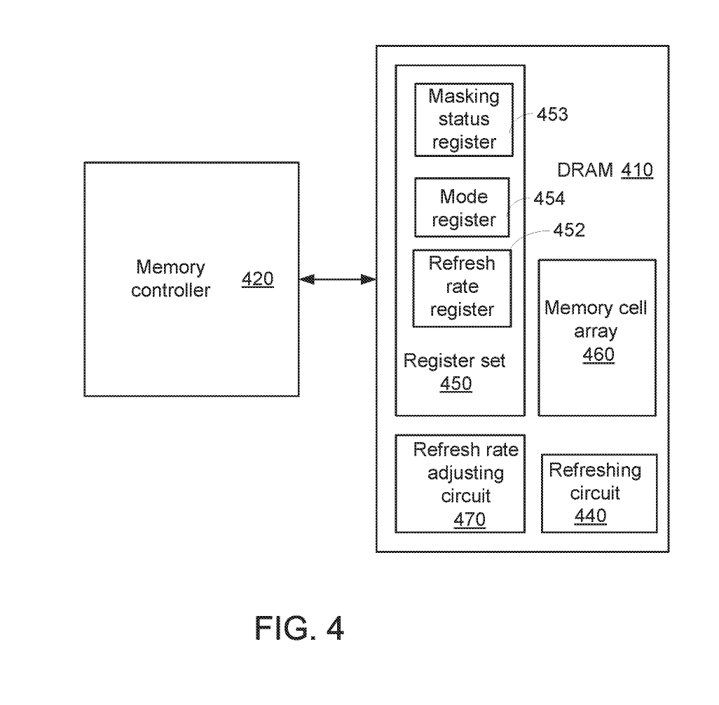

FIG. 4 schematically illustrates the architecture of a memory system according to a second embodiment of the invention. As shown in FIG. 4, the memory system comprises a memory controller 420 and a dynamic random access memory (DRAM) 410. The memory controller 420 is connected with a host (not shown). Moreover, the memory controller 420 may write data from the host to the DRAM 410, or the memory controller 420 may read data from the DRAM 410 and transmit the data to the host.

In this embodiment, the DRAM 410 comprises a memory cell array 460, a register set 450, a refreshing circuit 440 and a refresh rate adjusting circuit 470. The register set 450 comprises a refresh rate register 452, a mode register 454 and a masking status register 453. In another embodiment, the refresh rate register 452 and the masking status register 453 may be included in the mode register 454.

Since the data loss rate of the DRAM 410 is related to the ambient temperature, the DRAM 410 can automatically change the refresh information according to the ambient temperature. Moreover, the updated refresh information is stored in the refresh rate register 452 of the DRAM 410. Moreover, the refresh rate adjusting circuit 470 calculates a refresh rate according to the contents of the masking status register 453. The updated refresh rate is stored in the refresh rate register 452.

For example, assume that the refresh winoow t_{REFW} is 32 s and the required number of all-bank refresh commend in a refresh window t_{REFW} is 1000. If the memory cell array 460 comprises 8 unmasked memory banks, the refresh actions have to be performed on all unmasked memory banks of the DRAM 410 within the time period of 32 s. Under this circumstance, the all-bank refresh rate R_{ab} is 1/(32 s/1000)=1/(32 ms), and the per-bank refresh rate R_{pb} is 1/(32 s/8/1000)=1/(4 ms). In other words, the memory controller 420 has to issue a per-bank refresh command to different unmasked memory bank at a time interval of 4 ms, or issue a all-bank refresh command at a time interval of 32 ms.

In this embodiment, the memory controller 420 can further issue a masking command or an unmasking command to modify the contents of the masking status register 453. Then, the refresh rate adjusting circuit 470 updates the refresh rate according to the masking command or the unmasking command, and the updated refresh rate is stored in the refresh rate register 452. After reading the updated refresh rate from the refresh rate register 452, the memory controller 420 issues a refresh command to the DRAM 410 according to the updated refresh rate. The detailed operations will be described as follows.

For example, in the bank mask mode, the memory cell array 460 has totally Q memory banks and M memory banks are unmasked memory banks and (Q-M) memory banks are masked memory banks. Also, the refresh information stored in the refresh rate register 452 indicting the present all-bank refresh rate R_{ab,present}. Therefore, the present per-bank refresh rate R_{pb,present} is bigger or equal to M×R_{ab,presen} (R_{pb,present}≥M×R_{ab,present}).

If the memory controller 420 issues the masking command or the unmasking command to modify the contents of the masking status register 453 and the M unmasked memory banks are modified to N unmasked memory banks, the refresh rate adjusting circuit 470 calculates a next per-bank refresh rate R_{pb,next} and stores the next per-bank refresh rate into the refresh rate register 452. That is, R_{pb,next}≥(N/M)×R_{pb,present}.

After the memory controller 420 reads the next per-bank refresh rate R_{pb,next} from the refresh rate register 452, the memory controller 420 issues the per-bank refresh command to the DRAM 410 according to the next per-bank refresh rate R_{pb,next}. According to the per-bank refresh command, the refreshing circuit performs the per-bank refresh action. As mentioned above, the per-bank refresh rate is increased when the number of the unmasked memory banks is increased (i.e., N>M), and the per-bank refresh rate is decreased when the number of the unmasked memory banks is decreased N<M).

In the bank mask mode, the all-bank refresh rate R_{ab} is not influenced by the bank masking command or the bank unmasking command. After the memory controller 420 issues the masking command or the unmasking command to modify the contents of the masking status register 453, the refresh rate adjusting circuit 470 will not update the all-bank refresh rate R_{ab}. That is, the all-bank refresh rate R_{ab} stored in the refresh rate register 452 is not changed. While the all-bank refresh command is executed, a DRAM refresh pointer will jump over the masked memory banks and point to the unmasked memory banks according to the contents of the masking status register 453. The refreshing circuit 440 then performs the refresh action on the unmasked memory banks and does not perform the refresh action on the masked memory banks in response to the DRAM refresh pointer. The same, the all-bank refresh command can be replaced by the multi-banks refresh command or bank-group refresh command. In this situation, the refresh action is performed on the unmasked memory banks but not performed on the masked memory banks.

For example, in the segment mask mode, the memory cell array 460 comprises X unmasked memory segments, and the present all-bank refresh rate R_{ab,present} and the present per-bank refresh rate R_{pb,present} are stored in the refresh rate register 452.

If the memory controller 420 issues the masking command or the unmasking command to modify the contents of the masking status register 453 and the X unmasked memory segments are modified to Y unmasked memory segments, the refresh rate adjusting circuit 470 calculates a next all-bank refresh rate R_{ab,next} and a next per-bank refresh rate R_{pb,next}. The next all-bank refresh rate R_{pb,next} and the next per-bank refresh rate R_{pb,next} are stored into the refresh rate register 452. That is, R_{ab,next}≥(Y/X)×R_{ab,present}, and R_{pb,next}≥(Y/X)×R_{pb,present}. In addition, the next all-bank refresh rate R_{ab,next} or the next per-bank refresh rate R_{pb,next} may not store to refresh rate register 452 immediately.

After the memory controller 420 reads the next all-bank refresh rate R_{ab,next} from the refresh rate register 452, the memory controller 420 issues the all-bank refresh command to the DRAM 410 according to the next all-bank refresh rate. When the all-bank refresh command is executed, the refreshing circuit 440 of the DRAM 410 performs the all-bank refresh action on the unmasked memory segments of all memory banks.

After the memory controller 420 reads the next per-bank refresh rate R_{pb,next} from the refresh rate register 452, the memory controller 420 issues the per-bank refresh command to the DRAM 410 according to the next per-bank refresh rate. When the per-bank refresh command is executed, the refreshing circuit 440 of the DRAM 410 performs the per-bank refresh action on the unmasked memory segments of the memory bank corresponding to the per-bank refresh command.

For example, in the hybrid mode, the memory cell array 460 comprises M unmasked memory banks and X unmasked memory segments, and the present all-bank refresh rate R_{ab,present} and the present per-bank refresh rate R_{pb,present} are stored in the refresh rate register 452.

If the memory controller 420 issues the masking command or the unmasking command to modify the contents of the masking status register 453, the M unmasked memory banks are modified to N unmasked memory banks and the X unmasked memory segments are modified to Y unmasked memory segments, the refresh rate adjusting circuit 470 calculates a next all-bank refresh rate R_{ab,next} and a next per-bank refresh rate R_{pb,next}. The next all-bank refresh rate R_{ab,next} and the next per-bank refresh rate R_{pb,next} are stored into the refresh rate register 452. That is, R_{ab,next}≥(Y/X)×R_{ab,present}, and R_{pb,next}≥(N/M)×(Y/X)×R_{pb,present}. In addition, the next all-bank refresh rate R_{ab,next} or the next per-bank refresh rate R_{pb,next} may not store to refresh rate register 452 immediately.

After the memory controller 420 reads the next all-bank refresh rate R_{ab,next} from the refresh rate register 452, the memory controller 420 issues the all-bank refresh command to the DRAM 410 according to the next all-bank refresh rate. When the all-bank refresh command is executed, the refreshing circuit 440 of the DRAM 410 performs the all-bank refresh action on the unmasked memory segments of the unmasked memory banks.

After the memory controller 420 reads the next per-bank refresh rate R_{pb,next} from the refresh rate register 452, the memory controller 420 issues the per-bank refresh command to the DRAM 410 according to the next per-bank refresh rate. When the per-bank refresh command is executed, the refreshing circuit 440 of the DRAM 410 performs the per-bank refresh action on the unmasked memory segments of the memory bank.

When the memory controller 420 is in a normal working state, the memory controller 420 issues the masking command or the unmasking command to set the masking status register 453. In addition, the refresh rate adjusting circuit 470 calculates the next refresh rate and stored the next refresh rate in the refresh rate register 452. Then, the memory controller 420 reads the updated refresh rate from the refresh rate register 452 and generates the refresh command to the DRAM 410 according to the next refresh rate.

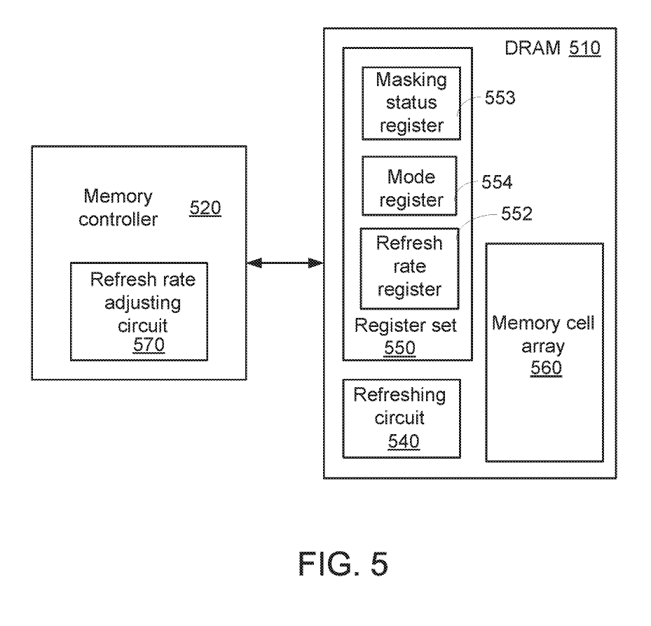

FIG. 5 schematically illustrates the architecture of a memory system according to a third embodiment of the invention. As shown in FIG. 5, the memory system comprises a memory controller 520 and a dynamic random access memory (DRAM) 510. In comparison with the second embodiment, the memory controller 520 comprises a refresh rate adjusting circuit 570 and the DRAM 510 is not equipped with the refresh rate adjusting circuit.

The memory controller 520 is connected with a host (not shown). Moreover, the memory controller 520 may write data from the host to the DRAM 510, or the memory controller 520 may read data from the DRAM 510 and transmit the data to the host.

In this embodiment, the DRAM 510 comprises a memory cell array 560, a register set 550 and a refreshing circuit 540. The register set 550 comprises a refresh rate register 552, a masking status register 553 and a mode register 554. In another embodiment, the refresh rate register 552 and the masking status register 553 may be included in the mode register 554.

In this embodiment, the memory controller 520 issues a masking command or an unmasking command to modify the contents of the masking status register 553. Then, the memory controller 520 read the refresh information from the refresh rate register 552 and the refresh rate adjusting circuit 570 updates the refresh rate. According to the updated refresh rate, the memory controller 520 issues a refresh command to the DRAM 510. The detailed operations will be described as follows.

For example, in the bank mask mode, the memory cell array 560 has totally Q memory banks and M memory banks are unmasked memory banks and (Q-M) memory banks are masked memory banks. Also, the refresh information stored in the refresh rate register 552 indicating the present all-bank refresh rate R_{ab,present}. Therefore, the present per-bank refresh rate R_{pb,present} is bigger or equal to M×R_{ab,presen} (R_{pb,present}≥M×R_{ab,present}).

If the memory controller 520 issues the masking command or the unmasking command to modify the contents of the masking status register 553 and the M unmasked memory banks are modified to N unmasked memory banks, the refresh rate adjusting circuit 570 calculates a next per-bank refresh rate R_{pb,next}. That is, R_{pb,next}≥(WM)×R_{pb,present}. Furthermore, the refresh information stored in the refresh rate register 552 indicating the present per-bank refresh rate is R_{pb,DRAM}, then R_{pb,next}≥(N/Q)×R_{pb,DRAM}.

After the refresh rate adjusting circuit 570 calculates the next per-bank refresh rate R_{pb,next}, the memory controller 520 issues the per-bank refresh command to the DRAM 510 according to the next per-bank refresh rate. According to the per-bank refresh command, the refreshing circuit 540 performs the per-bank refresh action. As mentioned above, the per-bank refresh rate is increased by the refresh rate adjusting circuit 570 when the number of the unmasked memory banks is increased (i.e., N>M), and the per-bank refresh rate is decreased by the refresh rate adjusting circuit 570 when the number of the unmasked memory banks is decreased (i.e., N<M).

In the bank mask mode, the all-bank refresh rate R_{ab,present} is not influenced by the bank masking command or the bank unmasking command. After the memory controller 520 issues the masking command or the unmasking command to modify the contents of the masking status register 553, the refresh rate adjusting circuit 570 will not update the all-bank refresh rate R_{ab,present}. While the all-bank refresh command is executed, the refreshing circuit 540 performs the refresh operation on the unmasked memory banks according to the contents of the masking status register 553.

In the segment mask mode, the memory cell array 560 has totally Q memory banks including Z memory segments. Also, X memory segments are unmasked memory segments and (Z-X) segments are masked memory segments. Furthermore, the refresh information stored in the refresh rate register 552 indicating the all-bank refresh rate is R_{ab,DRAM}, and the per-bank refresh rate is R^{ab,DRAM}. Therefore, the present all-bank refresh rate R_{ab,present}=R_{ab,DRAM}, the present per-bank refresh rate R_{pb,present} is bigger or equal to Q×R_{ab,presen} (R_{pb,present}≥Q×R_{ab,present}).

If the memory controller 520 issues the masking command or the unmasking command to modify the contents of the masking status register 553 and the X unmasked memory segments are modified to Y unmasked memory segments, the refresh rate adjusting circuit 570 calculates a next all-bank refresh rate R_{ab,next} and a next per-bank refresh rate R_{pb,next}. That is, R_{ab,next}≥(Y/X)×R_{ab,present}, and R_{pb,next}≥(Y/X)×R_{pb,present}. Furthermore, the refresh information stored in the refresh rate register 552 indicating the all-bank refresh rate is R_{ab,DRAM}, and the per-bank refresh rate is R_{pb,DRAM}. R_{ab,next}≥(Y/Z)×R_{ab,DRAM}, and R_{pb,next}≥(Y/Z)×R_{pb,DRAM}. In addition, the next all-bank refresh rate R_{ab,next} or the next per-bank refresh rate R_{pb,next} may not be applied immediately.

After the next all-bank refresh rate R_{ab,next} is applied, the memory controller 520 issues the all-bank refresh command to the DRAM 510 according to the next all-bank refresh rate R_{ab,next}. When the all-bank refresh command is executed, the refreshing circuit 540 of the DRAM 510 performs the all-bank refresh action on the unmasked memory segments of all memory banks corresponding to the contents of the masking status register 553. After the next per-bank refresh rate R_{pb,next} is applied, the memory controller 520 issues the per-bank refresh command to the DRAM 510 according to the next per-bank refresh rate R_{pb,next}. When the per-bank refresh command is executed, the refreshing circuit 540 of the DRAM 510 performs the per-bank refresh action on the unmasked memory segments of the memory bank.

Moreover, in the segment mask mode, the number of the unmasked memory segments in the memory cell array 560 is increased after the memory controller 520 issues the unmasking command. Consequently, the next all-bank refresh rate and the next per-bank refresh rate are both increased. Under this circumstance, the memory controller 520 immediately applies the all-bank refresh command or the per-bank refresh command to the DRAM 510 according to the next all-bank refresh rate R_{ab,next} or the next per-bank refresh rate R_{pb,next}.

On the other hand, the number of the unmasked memory segments in the memory cell array 560 is decreased after the memory controller 520 issues the masking command. Consequently, the next all-bank refresh rate and the next per-bank refresh rate are both decreased. Under this circumstance, the memory controller 520 cannot immediately apply the all-bank refresh command or the per-bank refresh command to the DRAM 510 according to the next all-bank refresh rate R_{ab,next} or the next per-bank refresh rate R_{pb,next}.

After the memory controller 520 confirms that the refresh actions on all memory segments comply with the specification of the refresh window t_{REFW}, the memory controller 520 issues the all-bank refresh command or the per-bank refresh command to the DRAM 510 according to the next all-bank refresh rate R_{ab,next} or the next per-bank refresh rate R_{pb,next}.

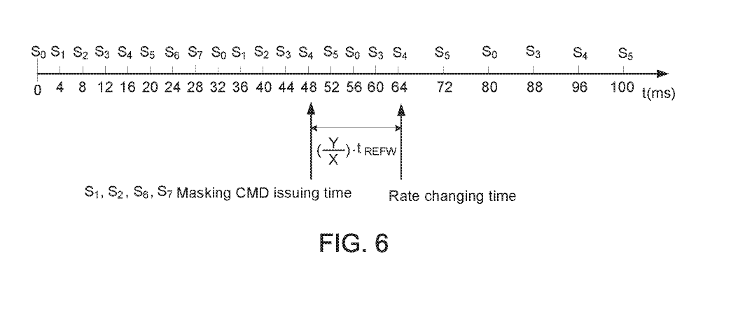

FIG. 6 is a schematic timing diagram illustrating the relationship between the masked command and the refresh rate according to the third embodiment of the invention. For example, the memory cell array 560 comprises 8 unmasked memory segments S₀˜S₇, and the refresh window t_{REFW} is 32 ms, the required number of all-bank refresh commands in a refresh window t_{REFW} is R_{cmd}=8 (i.e. one all-bank refresh command for one segment). Under this circumstance, the all-bank refresh rate R_{ab} is 1/(4 ms). In other words, the memory controller 520 has to issue an all-bank refresh command at a time interval of 4 ms.

Please refer to FIG. 6. At the time point 0 ms, the memory controller 520 issues an all-bank refresh command and the refresh pointer is at S₀. At the time point 4 ms, the memory controller 520 issues an all-bank refresh command and the refresh pointer is at S₁. At the time point 8 ms, the memory controller 520 issues an all-bank refresh command and the refresh pointer is at S₂. The rest may be deduced by analogy. In other words, the memory controller 520 issues 8 all-bank refresh commands for segment S₀˜5₇ between the time point 0 ms and the time point 32 ms.

Similarly, the memory controller 520 issues the all-bank refresh commands at the same all-bank refresh rate is R_{ab,present} after the time point 32 ms.

After the time point 48 ms (for example, 48.1 ms), the memory controller 520 issues a masking command to update the masking status register 553. According to the masking command, the memory segments S₁, S₂, S₆ and S₇ are set as the masked memory segments. That is, the X unmasked memory segments are modified to Y unmasked memory segments by the memory controller 520, wherein X=8 and Y=4. The refresh rate adjusting circuit 570 calculates a next all-bank refresh rate R_{ab,next}. That is, R_{ab,next}=(4/8)×R_{ab,present}=1/(8 ms). Under this circumstance, the memory controller 520 issues one all-bank refresh command at a time interval of 8 ms.

As mentioned above, the memory controller 520 has to confirm that the refresh actions on all memory segments comply with the specification of the refresh window t_{REFW}. In addition, there is a limitation of DRAM, maximum interval between two REFab, t_{MAXREFab2REFab}. Consequently, after the masking command has been issued for a specified time period, the present all-bank refresh rate is R_{ab,present} is kept unchanged. Then, the all-bank refresh rate is R_{ab,present} is changed to the next all-bank refresh rate R_{ab,next} after a specified time period. The specified time period is obtained by the formula: (Y/Z)×t_{REFW}−t_{MAXREFab2REFab}≥(4/8)×32 ms−t_{MAXREFab2REFab}=16 ms−t_{MAXREFab2REFab}. However, if the specified time period is longer than 16 ms, it is still comply with the specification. In FIG. 6, t_{MAXREFab2REFab} is assumed to be zero.

Consequently, the present all-bank refresh rate is R_{ab,present} is kept unchanged by the memory controller 520 between the time point 48.1 ms and the time point 64.1 ms (i.e., 48.1 ms+16 ms=64.1 ms). At the time point 64.1 ms, the all-bank refresh rate R_{ab,present} is changed to the next all-bank refresh rate R_{ab,next} by the refresh rate adjusting circuit 570. That is, the memory controller 520 issues an all-bank refresh command to perform the refresh action on the unmasked memory segments S₄, S₅, S₀ and S₃. The rest may be deduced by analogy. In addition, the per-bank refresh rate R_{pb,next}≥R_{ab,next}*(number of unmasked banks) and R_{pb,present}≥R_{ab,present}*(number of unmasked banks).

For example, in the hybrid mode, the memory cell array 560 has totally Q memory banks indicating Z memory segments. Also, M memory banks are unmasked memory banks and X memory segment are unmasked memory segments. Moreover, the present all-bank refresh rate is R_{ab,present}, and the present per-bank refresh rate is R_{pb,present}.

If the memory controller 520 issues the masking command or he unmasking command to modify the contents of the masking status register 553, the M unmasked memory banks are modified to N unmasked memory banks and the X unmasked memory segments are modified to Y unmasked memory segments, the refresh rate adjusting circuit 570 calculates a next all-bank refresh rate R_{ab,next} and a next per-bank refresh rate R_{pb,next}. That is, R_{ab,next}≥(Y/Z)×R_{ab,DRAM}, and R_{pb,next}≥(N/Q)×(Y/Z)×R_{pb,DRAM}.

If the memory controller 420 issues the masking command or the unmasking command to modify the contents of the masking status register 453, the M unmasked memory banks are modified to N unmasked memory banks and the X unmasked memory segments are modified to Y unmasked memory segments, the refresh rate adjusting circuit 470 calculates a next all-bank refresh rate R_{ab,next} and a next per-bank refresh rate R_{pb,next}. That is, R_{ab,next}≥(Y/Z)×R_{ab,unmasked}, and R_{pb,next}≥(N/Q)×(Y/Z)×R_{pb,unmasked}.

After the next all-bank refresh rate R_{ab,next} is updated, the memory controller 520 issues the all-bank refresh command to the DRAM 510 according to the next all-bank refresh rate R_{ab,next}. When the all-bank refresh command is executed, the refreshing circuit 540 of the DRAM 510 performs the all-bank refresh action on the unmasked memory segments of all the unmasked memory banks according to the contents of the masking status register 453.

After the next per-bank refresh rate R_{pb,next} is updated, the memory controller 520 issues the per-bank refresh command to the DRAM 510 according to the next per-bank refresh rate. When the per-bank refresh command is executed, the refreshing circuit 540 of the DRAM 510 performs the per-bank refresh action on the unmasked memory segments of the memory bank.

Moreover, in the hybrid mode, the number of the unmasked memory segments in the memory cell array 560 is increased after the memory controller 520 issues the unmasking command. Consequently, the next all-bank refresh rate and the next per-bank refresh rate are both increased. Under this circumstance, the memory controller 520 immediately applies the all-bank refresh command or the per-bank refresh command to the DRAM 510 according to the next all-bank refresh rate R_{ab,next} or the next per-bank refresh rate R_{pb,next}.

On the other hand, the number of the unmasked memory segments in the memory cell array 560 is decreased after the memory controller 520 issues the masking command. Consequently, the next all-bank refresh rate and the next per-bank refresh rate are both decreased. Under this circumstance, the memory controller 520 cannot immediately apply the all-bank refresh command or the per-bank refresh command to the DRAM 510 according to the next all-bank refresh rate R_{ab,next} or the next per-bank refresh rate R_{pb,next}. After the memory controller 520 confirms that the refresh actions on all memory segments comply with the specification of the refresh window t_{REFW}, the memory controller 520 applies the all-bank refresh command or the per-bank refresh command to the DRAM 510 according to the next all-bank refresh rate R_{ab,next} or the next per-bank refresh rate R_{pb,next}. The operations are similar to those of FIG. 6, and are not redundantly described herein.

When the memory controller 520 is in a normal working state, the memory controller 520 issues the masking command or the unmasking command to set the masking status register 553. In addition, the refresh rate adjusting circuit 570 calculates the next refresh rate. Then, the memory controller 520 generates the refresh command to the DRAM 510 according to the next refresh rate.

From the above descriptions, the invention provides the memory system and the refresh control method. After the masking status register is set by the memory controller, the memory cell array of the DRAM is divided into a masked region and an unmasked region. After the memory controller issues the refresh command to the DRAM, the refreshing circuit performs the refresh action on the unmasked region of the memory cell array. Consequently, the partial-array refreshing purpose is achieved.

According to the invention, the memory controller is capable of dynamically setting an unmasked region and a masked region in the memory cell array. Thus, the memory controller needs not to comply with the all bank refresh cycle time tREFC_{ab} defined in the DRAM specification. When the memory controller is in the normal working state, the memory controller is capable of issuing two consecutive all-bank refresh commands having a time interval smaller than the all bank refresh cycle time tREFC_{ab}.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A refresh control method for a memory system, the memory system comprising a dynamic random access memory with a register set and a memory cell array, the refresh control method comprising steps of:
updating the register set to divide the memory cell array into a first region and a second region wherein the first is set as a masked region, and the second region is set as an unmasked region; and
issuing a refresh command to the dynamic random access memory, wherein according to the refresh command, a refresh action is performed on the second region of the memory cell array.

2. The refresh control method as claimed in claim 1, wherein the memory cell array comprises plural memory banks, the first region is masked memory banks of the plural memory banks, and the second region is unmasked memory banks of the plural memory banks.

3. The refresh control method as claimed in claim 2, wherein the refresh command is a per-bank refresh command, and the refresh action is performed on the banks in the second region according to the per-bank refresh command, and the refresh action is not performed on the bank in the first region.

4. The refresh control method as claimed in claim 2, wherein the refresh command is an all-bank refresh command or a multi-banks refresh command or a bank-group refresh command, and the refresh action is performed on the banks in the second region but not performed on the banks in the first region.

5. The refresh control method as claimed in claim 1, wherein the memory cell array comprises plural memory banks, and each of the plural memory banks comprises plural memory segments, wherein the first region is masked memory segments of the plural memory banks, and the second region is unmasked memory segments of the plural memory banks.

6. The refresh control method as claimed in claim 5, wherein the refresh command is a per-bank refresh command, and the refresh action is performed on the second region but not performed on the first region, and the refresh action is performed on the bank according to the per-bank refresh command.

7. The refresh control method as claimed in claim 5, wherein the refresh command is an all-bank refresh command or a multi-banks refresh command or a bank-group refresh command, and the refresh action is performed on the banks of the second region but not performed on the banks of the first region.

8. The refresh control method as claimed in claim 1, wherein the memory cell array comprises plural memory banks, and each of the plural memory banks comprises plural memory segments, wherein the first region comprises masked memory segments, and the second region comprises unmasked memory segments.

9. The refresh control method as claimed in claim 8, wherein the refresh command is a per-bank refresh command, and the refresh action is performed on the bank of the second region according to the per-bank refresh command but not performed on the banks of the first region.

10. The refresh control method as claimed in claim 8, wherein the refresh command is an all-bank refresh command or a multi-banks refresh command or a bank-group refresh command, and the refresh action is performed on the banks of the second region but not performed on the banks of the first region.

11. The refresh control method as claimed in claim 1, further comprising a step of receiving a refresh information from the dynamic random access memory and periodically issuing the refresh command to the dynamic random access memory according to the refresh information.

12. The refresh control method as claimed in claim 1, further comprising a step of calculating a refresh rate according to the contents of the register set and periodically issuing the refresh command to the dynamic random access memory according to the refresh rate.

13. The refresh control method as claimed in claim 12, further comprising a step of periodically issuing the refresh command to the dynamic random access memory according to the refresh rate after confirming that the refresh action complies with a specification of a refresh window.

14. The refresh control method as claimed in claim 1, wherein the refresh command is an all-bank refresh command and a memory controller of the memory system issues two consecutive all-bank refresh commands having a time interval smaller than an all bank refresh cycle time.

15. A memory controller connected with a dynamic random access memory, the dynamic random access memory comprising a memory cell array, a register set and a refreshing circuit, and the memory controller capable of setting the register set, wherein the memory controller sets a first region of the memory cell array as a masked region and sets a second region of the memory cell array as an unmasked region,
wherein after the memory controller issues a refresh command to the dynamic random access memory, the refreshing circuit performs a refresh action on the second region of the memory cell array according to the refresh command.

16. The memory system as claimed in claim 15, wherein the memory cell array comprises plural memory banks, the first region is masked memory banks of the plural memory banks, and the second region is unmasked memory banks of the plural memory banks.

17. The memory system as claimed in claim 16, wherein the refresh command is a per-bank refresh command, and the refreshing circuit performs the refresh action on the banks of the second region according to the per-bank refresh command but does not perform the refresh action on the banks of the first region.

18. The memory system as claimed in claim 16, wherein the refresh command is an all-bank refresh command or a multi-banks refresh command or a bank-group refresh command, and the refreshing circuit performs the refresh action on the banks of the second region but does not perform the refresh action on the banks of the first region.

19. The memory system as claimed in claim 15, wherein the memory cell array comprises plural memory banks, and each of the plural memory banks comprises plural memory segments, wherein the first region is masked memory segments of the plural memory banks, and the second region is unmasked memory segments of the plural memory banks.

20. The memory system as claimed in claim 19, wherein the refresh command is a per-bank refresh command, and the refreshing circuit performs the refresh action on the second region but not performs on the first region, and the refreshing circuit performs the refresh action on the bank according to the per-bank refresh command.

21. The memory system as claimed in claim 19, wherein the refresh command is an all-bank refresh command or a multi-banks refresh command or a bank-group refresh command, and the refreshing circuit performs the refresh action on the banks of the second region but not performed on the banks of the first region, and the refreshing circuit performs the refresh action on the bank according to the refresh command.

22. The memory system as claimed in claim 15, wherein the memory cell array comprises plural memory banks, and each of the plural memory banks comprises plural memory segments, wherein the first region comprises masked memory segments, and the second region comprises unmasked memory segments.

23. The memory system as claimed in claim 22, wherein the refresh command is a per-bank refresh command, and the refreshing circuit performs the refresh action on a bank of the second region according to the per-bank refresh command and does not perform the refresh action on the bank of the first region.

24. The memory system as claimed in claim 22, wherein the refresh command is an all-bank refresh command or a multi-banks refresh command or a bank-group refresh command, and the refreshing circuit performs the refresh action on the banks of the second region according to the refresh command but does not perform on the banks of first region.

25. The memory system as claimed in claim 15, wherein the register set further comprises a refresh rate register, and the dynamic random access memory further comprises a refresh rate adjusting circuit, wherein the refresh rate adjusting circuit calculates a refresh rate according to the contents of the register set and stores the refresh rate into the refresh rate register.

26. The memory system as claimed in claim 15, wherein the memory controller comprises a refresh rate adjusting circuit, wherein the refresh rate adjusting circuit calculates a refresh rate according to the contents of the register set, masking command or the unmasking command, and the memory controller periodically issues the refresh command to the dynamic random access memory according to the refresh rate.

27. The memory system as claimed in claim 15, wherein the refresh command is a all-bank refresh command and a memory controller of the memory system issues two consecutive all-bank refresh commands having a time interval smaller than a all bank refresh cycle time.
